(19) United States
(12) Patent Application Publication
(10) Pub. No.: US 2011/0056533 A1
(43) Pub. Date: Mar. 10, 2011

(54) SERIES SOLAR SYSTEM WITH CURRENT-MATCHING FUNCTION

(76) Inventor: Kan-Sheng Kuan, Hsinchu City (TW)

(21) Appl. No.: 12/575,459

(22) Filed: Oct. 7, 2009

(30) Foreign Application Priority Data
Sep. 10, 2009 (TW) 098130511

(51) Int. Cl. H01L 31/042; H02J 1/00

(52) U.S. Cl. 136/244; 307/77

(57) ABSTRACT

A series solar system with current-matching function includes a plurality of solar modules. The plurality of the solar modules is electrically connected in series. Each solar module includes a DC/DC converter and a solar panel electrically connected in parallel. The photocurrent generated by the solar panel is matched with the current generated by the solar panel operating at the optimum operating point by means of adjusting the duty cycle of the DC/DC converter, so that the solar panel can generate maximum output power. Therefore, in the series solar system, even a solar module is covered, causing the received light intensity of the solar module is reduced, and the series solar system still can generate maximum output power.

### BACKGROUND OF THE INVENTION

1. Field of the Invention

The present invention is related to a solar system, and more particularly, to a solar system with current-matching function.

2. Description of the Prior Art

The solar panels are utilized for forming a solar system (power system) so as to convert the solar energy into electrical power. The solar panel can receive light beams and accordingly generates a photocurrent and a photovoltage. The solar system can be grid-connected for providing an output current and a load voltage. The solar system formed by the solar panels can be a series solar system (the solar panels are electrically connected in series), or a parallel solar system (the solar panels are electrically connected in parallel). Comparing with the parallel solar system, the series solar system can generate the higher load voltage and the smaller output current. Since the conduction loss can be reduced when the magnitude of the output current of the solar system is reduced, and, generally speaking, the voltage level of the load voltage required by the grid is quite high, the series solar system is more proper to be grid-connected than the parallel solar system.

Please refer to FIG. 1. FIG. 1 is a schematic diagram illustrating the relation between the photocurrent and the photovoltage generated by a solar panel. In FIG. 1, assume that the received light intensity of the solar panel is SUN_{H}, and the current-voltage curve (photocurrent-photovoltage curve) of the solar panel is CV_{H}. If the solar panel operates at the operating point O₁, that is, when the photocurrent generated by the solar panel is I₁ and the photovoltage generated by the solar panel is V₁, the solar panel generates the maximum output power. In other words, when the current-voltage curve of the solar panel is CV_{H}, the optimum operating point of the solar panel is O₁. When the received light intensity of the solar panel changes from SUN_{H} to SUN_{L}, the current-voltage curve of the solar panel changes from CV_{H} to CV_{L}. Meanwhile, if the solar panel operates at the operating point O₂, that is, when the photocurrent generated by the solar panel is I₂ and the photovoltage generated by the solar panel is V₂, the solar panel generates the maximum output power. In other words, when the current-voltage curve of the solar panel is CV_{L}, the optimum operating point of the solar panel is O₂. According to the above-mentioned, the optimum operating point of the solar panel varies with the received light intensity. In addition, when the current-voltage curve of the solar panel is CV_{L}, the maximum magnitude of the photocurrent that the solar panel can generate is around I₂. If the external circuit is to drain a current with a magnitude larger than I₂ (for example, I₁) from the solar panel, the solar panel may be damaged. Hence, in the prior art, a diode is connected to the solar panel in parallel for protecting the solar panel.

In the series solar system, assume that the current-voltage curve of each solar panel is the same as CV_{H} shown in FIG. 1. However, if one of the solar panels is covered by the falling leaves or the frost snow, the received light intensity of the covered solar panel decreases so that the current-voltage curve of the covered solar panel will change from CV_{H} to CV_{L}. In this way, the maximum magnitude of the photocurrent that the covered solar panel can generate is around I₂. Since in the series system, the magnitudes of the currents passing through the solar panels have to be the same, the photocurrents outputted by the other uncovered solar panels can not be larger than I₂. In other words, the other uncovered solar panels can not operate at the optimum operating point O₁ (generating the photocurrent I₁ and the photovoltage V₁). Therefore, in the series system, when one of the solar panels is covered, all the other uncovered solar panel are affected and can not generate the maximum output power, reducing the energy conversion efficiency of the series solar system.

### SUMMARY OF THE INVENTION

The objective of the present invention is to provide a series solar system that can generate the maximum power.

The present invention provides a series solar system with current-matching function. The series solar system is utilized for providing an output current and a load voltage. The series solar system comprises a plurality of solar modules electrically connected to each other in series. Each solar module comprises a solar panel, a DC/DC converter, and a feedback circuit. The solar panel is utilized for receiving light beams and generating a photocurrent and a photovoltage according to a light intensity. The DC/DC converter is electrically connected to the solar panel. The DC/DC converter is utilized for converting the photovoltage into an output voltage and converting the photocurrent into the output current according to a power-feedback signal. The feedback circuit is electrically connected to the DC/DC converter. The feedback circuit is utilized for generating the power-feedback signal according to the output voltage and the output current. A sum of output voltages generated by the plurality of the solar modules is equal to the load voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating the relation between the photocurrent and the photovoltage generated by a solar panel.

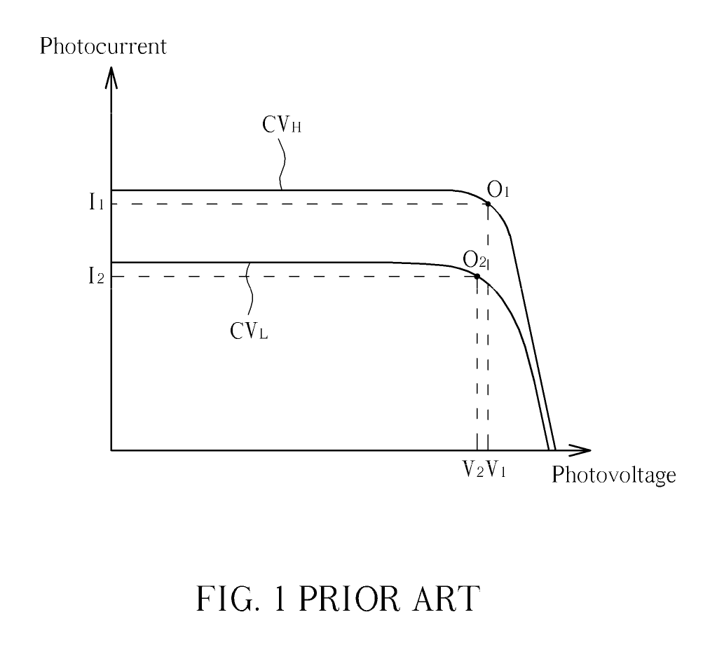

FIG. 2 is a diagram illustrating a solar module of the present invention.

FIG. 3A is a diagram illustrating the method that the controller adjusts the duty cycle of the power switch according to a first embodiment of the present invention.

FIG. 3B is a diagram illustrating the method that the controller adjusts the duty cycle of the power switch according to a second embodiment of the present invention.

FIG. 4 is a diagram illustrating that the solar panel can operate at the optimum operating point when the received light beams of the solar panel changes.

FIG. 5 is a diagram illustrating a DC/DC converter according to another embodiment of the present invention.

FIG. 6 is a diagram illustrating a series solar system of the present invention.

### DETAILED DESCRIPTION

In the series solar system of the present invention, the magnitudes of the currents passing through the solar panels of the series solar system do not have to be the same, by means of each solar panel connected to a DC/DC converter in parallel, and the photocurrent generated by each solar panel can be matching with the operating current corresponding to the optimum operating point. In this way, even one of the solar panels of the series solar system of the present invention is covered; each solar panel still can operate at the optimum operating point. Thus, each solar panel can generate the maximum output power, improving the energy conversion efficiency of the series solar system.

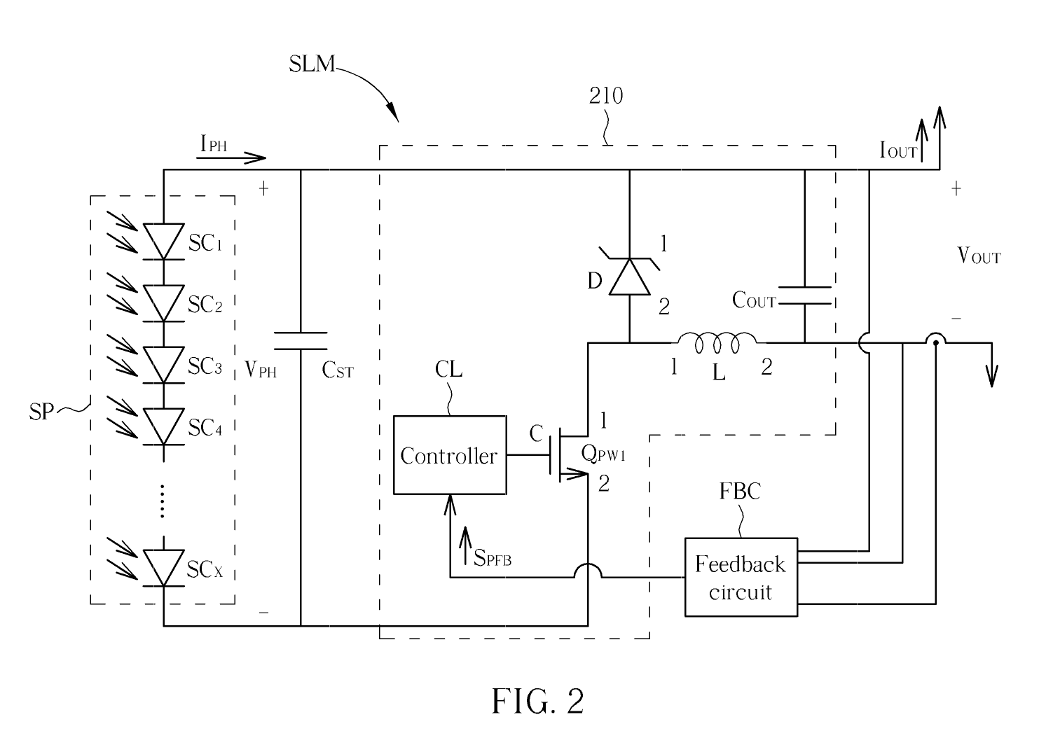

Please refer to FIG. 2. FIG. 2 is a schematic diagram illustrating a solar module SLM of the present invention. The solar module comprises a solar panel SP, a voltage-stabilizing capacitor C_{ST}, a DC/DC converter 210, and a feedback circuit FBC. The solar panel SP comprises solar cells SC₁˜SCₓ. The solar cells SC₁˜SCₓ are electrically connected to each other in series. The solar panel SP is utilized for receiving light beams so as to generate a photocurrent I_{PH} and a photovoltage V_{PH}. The voltage-stabilizing capacitor C_{ST} is electrically connected to the solar panel SP in parallel, and the voltage-stabilizing capacitor C_{ST} can stabilize the photovoltage V_{PH} generated by the solar panel SP. The feedback circuit FBC generates a power-feedback signal S_{PFB} according to an output voltage V_{OUT} and an output current I_{OUT} of the solar modules SLM. More particularly, the feedback circuit FBC detects the output voltage V_{OUT} and the output current I_{OUT} of the solar modules SLM, and accordingly calculates out the output power P of the solar modules SLM. For instance, the feedback circuit FBC can multiply the output current I_{OUT} and the output voltage V_{OUT} together for obtaining the output power P. In this way, the feedback circuit FBC can generate the power-feedback signal S_{PFB} representing the output power P. In this embodiment, the DC/DC converter 210 is a buck converter. The DC/DC converter 210 is utilized for converting the photovoltage V_{PH} into the output voltage V_{OUT}, and converting the photocurrent I_{PH} into the output current I_{OUT} according to the power-feedback signal S_{PFB}. The DC/DC converter 210 comprises an output capacitor C_{OUT}, a diode D, an inductor L, a power switch Q_{PW1}, and a controller CL. The electrically connecting relations between the components of the DC/DC converter 210 are shown in FIG. 2, and hence will not be repeated again for brevity. The output capacitor C_{OUT} is utilized for generating the output voltage V_{OUT}. The controller CL is utilized for controlling the power switch Q_{PW1} to be turned on or turned off. When the power switch Q_{PW1} is turned on, the output current I_{OUT} passes through the inductor L, the power switch Q_{PW1}, and the solar panel SP; meanwhile, the solar panel charges the inductor L. When the power switch Q_{PW1} is turned off, the output current I_{OUT} passes through the inductor L, and the diode D; meanwhile, the inductor L is in the discharging state for maintaining the magnitude of the output current I_{OUT}. For the solar module SLM generating the maximum output power, the controller CL adjusts the duty cycle of the power switch Q_{PW1} according to the power-feedback signal S_{PFB}, and the related operational principle is illustrated in detail as below.

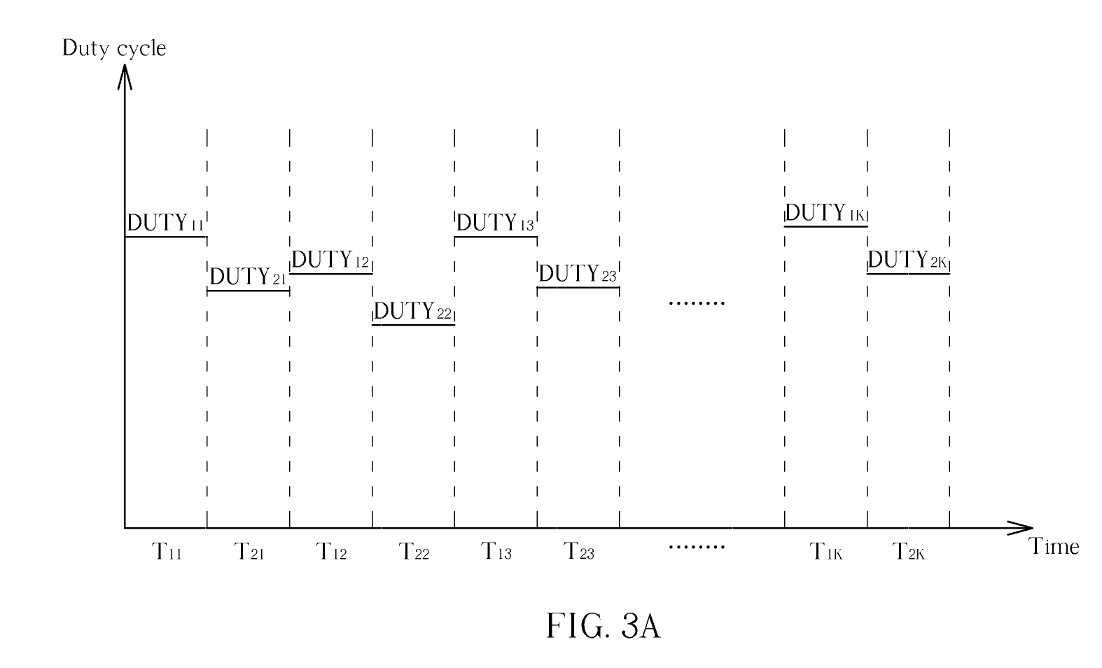

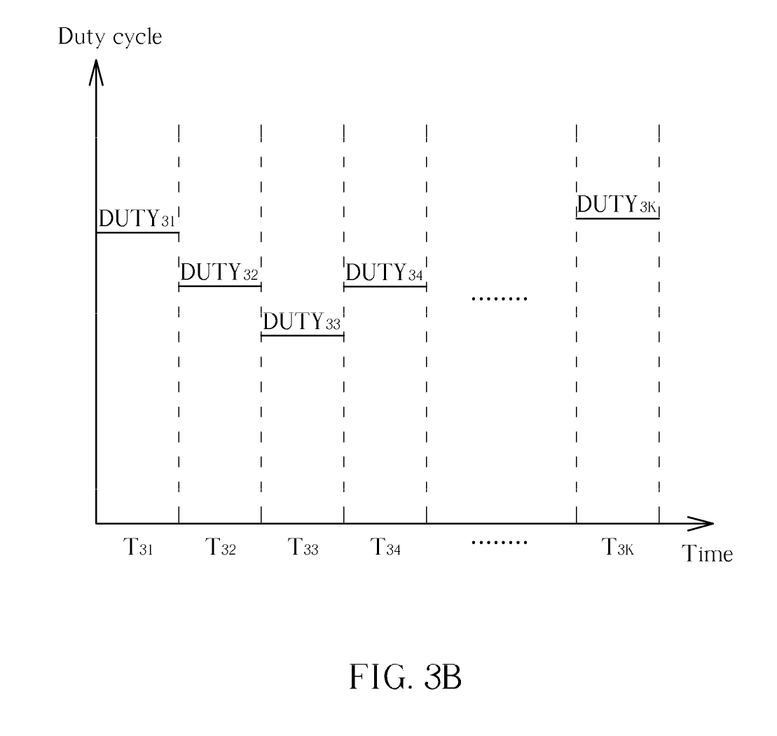

Please refer to FIG. 3A. FIG. 3A is a schematic diagram illustrating the method that the controller CL adjusts the duty cycle of the power switch Q_{PW1} according to the power-feedback signal S_{PFB}, according to the first embodiment of the present invention. The periods of the solar module SLM operating can be divided into the first detecting periods T₁₁˜T_{1K} and the second detecting periods T₂₁˜T_{2K}, wherein the period lengths of the first detecting periods T₁₁˜T_{1K} and the second detecting periods T₂₁˜T_{2K} are all equal to one cycle T. During the first detecting period T₁₁, the controller CL controls the power switch Q_{PW1} operating with the first duty cycle DUTY₁₁. That is, the DC/DC converter 210 operates with the first duty cycle DUTY₁₁ at the time. During the second detecting period T₂₁, the controller CL controls the power switch Q_{PW1} operating with the second duty cycle DUTY₂₁. That is, the DC/DC converter 210 operates with the second duty cycle DUTY₂₁ at the time. Assume that the second duty cycle DUTY₂₁ is smaller than the first duty cycle DUTY₂₁. That is, the turned-on period of the power switch Q_{PW1} during the first detecting period T₁₁ is longer than the turned-on period of the power switch Q_{PW1} during the second detecting period T₂₁. The controller CL receives the power-feedback signal S_{PFB21} corresponding to the second detecting period T₂₁ during the second detecting period T₂₁. The controller CL compares the power-feedback signal S_{PFB21} with the power-feedback signal S_{PFB11}. When the power-feedback signal S_{PFB21} is larger than the power-feedback signal S_{PFB11}, it represents that the output power P₂₁ outputted by the solar module SLM during the second detecting period T₂₁ is larger than the output power P₁₁ outputted by the solar module SLM during the first detecting period T₁₁. Since the second duty cycle DUTY₂₁ is smaller than the first duty cycle DUTY₁₁, it represents that the DC/DC converter 210 has to decrease the duty cycle for the solar module SLM generating a larger output power at the time. Consequently, the controller CL decreases the first duty cycle from DUTY₁₁ to DUTY₁₂ during the succeeding first detecting period T₁₂ so the DC/DC converter 210 operates with the first duty cycle DUTY₁₂ smaller than the first duty cycle DUTY₁₁, and the controller CL decreases the second duty cycle from DUTY₂₁ to DUTY₂₂ during the succeeding second detecting period T₂₂ so the DC/DC converter 210 operates with the second duty cycle DUTY₂₂ smaller than the second duty cycle DUTY₂₁. If the received power-feedback signal S_{PFB22} of the controller CL during the second detecting period T₂₂ is smaller than the received power-feedback signal S_{PFB12} of the controller CL during the first detecting period T₁₂, since the second duty cycle DUTY₂₁ is smaller than the corresponding first duty cycle DUTY₁₁, it represents the DC/DC converter 210 has to increase the duty cycle for the solar module SLM generating a larger output power at the time. Therefore, the controller CL increases the first duty cycle from during the succeeding first detecting period T₁₃ so the DC/DC converter 210 operates with the first duty cycle DUTY₁₃ larger than the first duty cycle DUTY₁₂, and the controller CL increases the second duty cycle during the succeeding second detecting period T₂₃ so the DC/DC converter 210 operates with the second duty cycle DUTY₂₃ larger than the second duty cycle DUTY₂₂. Hence, the controller CL can repeatedly compare the received power-feedback signal during the first detecting period with the received power-feedback signal during the second detecting period by means of the above-mentioned method, and accordingly adjusts the duty cycle of the DC/DC converter 210 for the solar module SLM generating the maximum output power.

Please refer to FIG. 3B. FIG. 3B is a schematic diagram illustrating the method that the controller CL adjusts the duty cycle of the power switch Q_{PW1} according to the power-feedback signal S_{PFB}, according to the second embodiment of the present invention. The periods of the solar module SLM operating can be divided into the detecting periods T₃₁˜T_{3K}, wherein the period lengths of the detecting periods T₃₁˜T_{3K} are all equal to one cycle T. In FIG. 3B, the controller CL controls the power switch Q_{PW1} operating with the duty cycle DUTY₃₁ during the detecting period T₃₁; the controller CL controls the power switch Q_{PW1} operating with the duty cycle DUTY₃₂ during the detecting period T₃₂, wherein the duty cycle DUTY₃₂ is smaller than the duty cycle DUTY₃₁. If the received power-feedback signal S_{PFB32} of the controller CL corresponding to the detecting period T₃₂ is larger than the received power-feedback signal S_{PFB31} of the controller CL corresponding to the detecting period T₃₁, it represents that the controller CL has to decrease the duty cycle of the power switch Q_{PW1} for the solar module SLM generating a large output power. As a result, the controller CL decreases the duty cycle of the power switch Q_{PW1} from DUTY₃₂ to DUTY₃₃ during the detecting period T₃₃. When the received power-feedback signal S_{PFB33} of the controller CL during the detecting period T₃₃ is smaller than the received power-feedback signal S_{PFB32} of the controller CL during the detecting period T₃₂, it represents that the controller CL has to increase the duty cycle of the power switch Q_{PW1} for the solar module SLM generating a larger output power. Thus, the controller CL increases the duty cycle DUTY₃₄ of the power switch Q_{PW1} during the detecting period T₃₄. In this way, the controller CL can repeatedly compare the received power-feedback signal during a detecting period with the received power-feedback signal during a prior detecting period adjacent to the detecting period by means of the above-mentioned method, and accordingly adjusts the duty cycle of the DC/DC converter 210 for the solar module SLM generating the maximum output power.

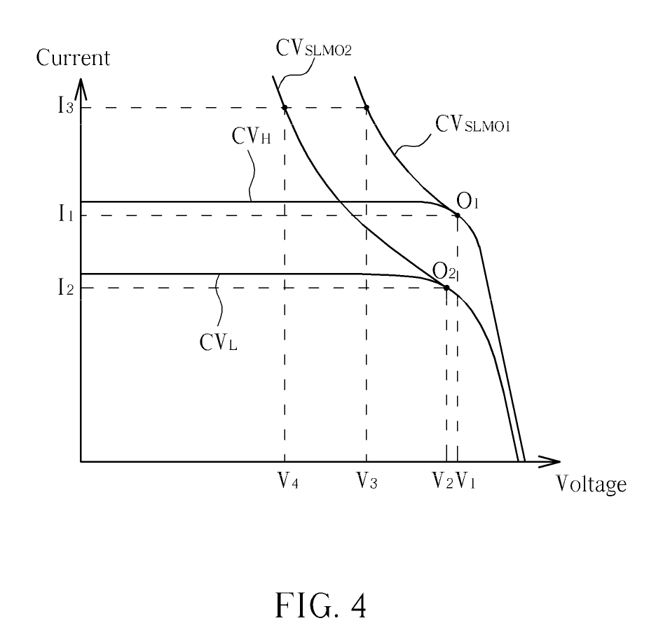

Please refer to FIG. 4. FIG. 4 is a schematic diagram illustrating that the solar panel SP can operate at the optimum operating point when the received light beams of the solar panel SP changes. Assume that the output current I_{OUT} of the solar module SLM is limited to be I₃ by an external load. At the first, the received light intensity of the solar panel is SUN_{H}, and the current-voltage curve of the solar panel SP is CV_{H}. Meanwhile, the controller CL can adjust the duty cycle of the power switch Q_{PW1} by means of the methods illustrated in FIG. 3A and FIG. 3B, so that the solar panel SP can operate at the optimum operating point O₁ (that is, the photocurrent generated by the solar panel SP is I₁, and the photovoltage generated by the solar panel SP is V₁) of the current-voltage curve CV_{H}. In FIG. 4, the curve CV_{SLMO1} represents the relation between the output current I_{OUT} and the output voltage V_{OUT} generated by the solar module SLM when the solar panel SP operates at the operating point O₁, by means of the DC/DC converter 210. Since the output current I_{OUT} of the solar module SLM is limited to be I₃, the output voltage V_{OUT} generated by the solar module SLM is V₃ according to the curve CV_{SLMO1}. When the received light intensity of the solar panel SP changes from SUN_{H} to SUN_{L} (for example, the solar panel SP is covered), the current-voltage curve of the solar panel SP becomes CV_{L}. The controller CL can adjust the duty cycle of the power switch Q_{PW1} by means of the methods illustrated in FIG. 3A and FIG. 3B, so that the solar panel SP still can operate at the optimum operating point O₂ (that is, the photocurrent generated by the solar panel SP is I₂, and the photovoltage generated by the solar panel SP is V₂) of the current-voltage curve CV_{L}. In FIG. 4, the curve CV_{SLMO2} represents the relation between the output current I_{OUT} and the output voltage V_{OUT} generated by the solar module SLM when the solar panel SP operates at the operating point O₂, by means of the DC/DC converter 210. Since the output current I_{OUT} of the solar module SLM is I₃, the output voltage V_{OUT} generated by the solar module SLM is V₄ according to the curve CV_{SLMO2}. Therefore, no matter the received light intensity of the solar panel SP is SUN_{H} or SUN_{L}, the DC/DC converter 210 can adjust the duty cycle according the methods illustrated in FIG. 3A and FIG. 3B so that the output power of the solar panel SP can be maximized in the different condition of the received light intensity (for example, SUN_{H} or SUN_{L}).

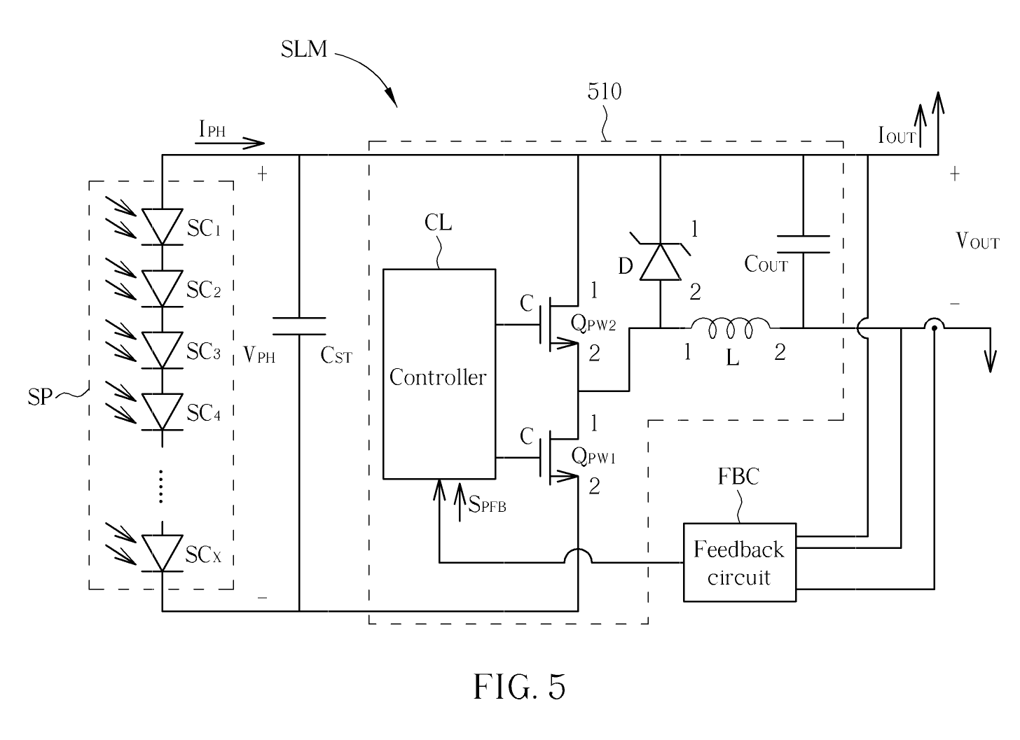

Please refer to FIG. 5. FIG. 5 is a schematic diagram illustrating a DC/DC converter 510 according to another embodiment of the present invention. The DC/DC converter 510 comprises an output capacitor C_{OUT}, an inductor L, power switches Q_{PW1} and Q_{PW2}, and a controller CL. Comparing with the DC/DC converter 210, the controller CL of the DC/DC converter 510 controls not only the power switch Q_{PW1}, but also the power switch Q_{PW2}. The power switches Q_{PW1} and Q_{PW2} are complementary to each other. That is, when the power switch Q_{PW1} is turned on, the power switch Q_{PW2} is turned off; when the power switch Q_{PW1} is turned off, the power switch Q_{PW2} is turned on. When the power switch Q_{PW1} is turned on and the power switch Q_{PW2} is turned off, the output current I_{OUT} passes through the inductor L, the power switch Q_{PW1}, and the solar panel SP. When the power switch Q_{PW1} is turned off and the power switch Q_{PW2} is turned on, the output current I_{OUT} passes through the inductor L and the power switch Q_{PW2}, meanwhile, the inductor L is in the discharging state for maintaining the magnitude of the output current I_{OUT}. In addition, the DC/DC converter 510 further comprises a diode D (as shown in FIG. 5). In this way, when the power switches Q_{PW1} and Q_{PW2} are in the dead-time state (that is, when the controller CL is to switch the power switches Q_{PW1} and Q_{PW2}, the power switches Q_{PW1} and Q_{PW2} may both be turned off for a short time), the output current I_{OUT} still can pass through the inductor L by the diode D, and the inductor L is in the discharging state for maintaining the magnitude of the output current I_{OUT} at the time. In the present embodiment, the controller CL of the DC/DC converter 510 still can control the solar panel SP operating at the optimum operating point by means of the methods illustrated in FIG. 3A and FIG. 3B, so that the output power generated by the solar module SLM can be maximized. For example, by means of the method illustrated in FIG. 3A, the controller CL controls the power switch Q_{PW1} operating with first duty cycles DUTY₁₁˜DUTY_{1K} during the first detecting periods T₁₁˜T_{1K} and operating with the second duty cycles DUTY₂₁˜DUTY_{2K} during the second detecting periods T₂₁˜T_{2K} according to the power-feedback signal S_{PFB}. In this way, the controller CL can adjust the first duty cycle and the second duty cycle of the power switch Q_{PW1} by means of comparing the received power-feedback signals during the first detecting periods with the received power-feedback signals during the second detecting periods. In addition, the diode D is a Schottky diode, and the power switches Q_{PW1} and Q_{PW2} are both Metal Oxide Semiconductor (MOS) transistors.

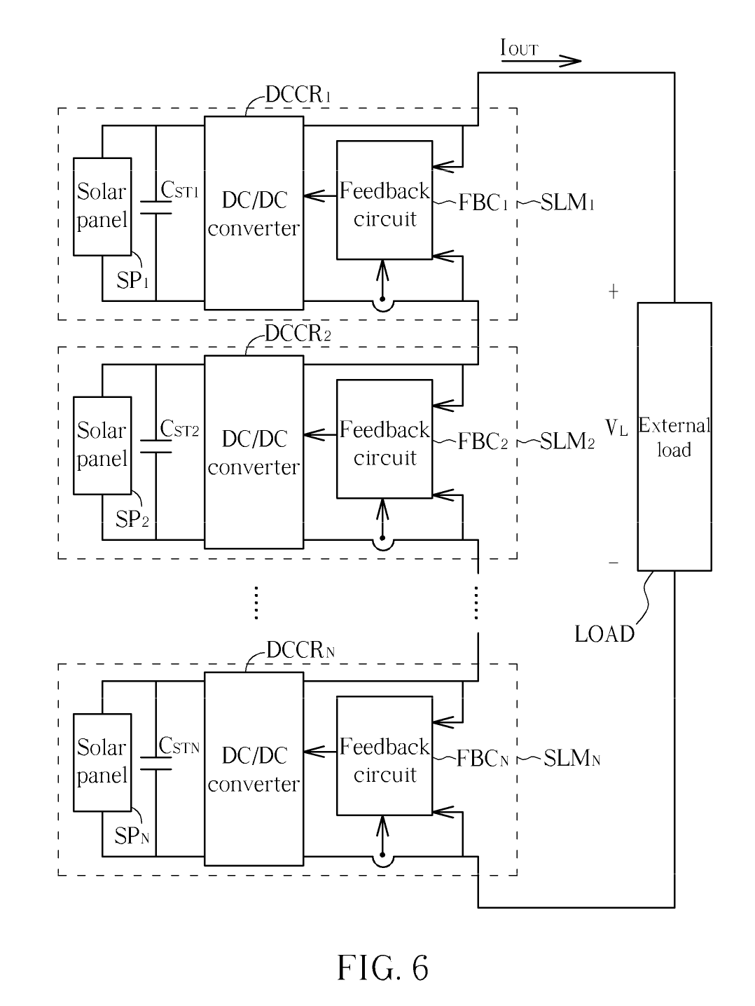

Please refer to FIG. 6. FIG. 6 is a schematic diagram illustrating a series solar system 600 of the present invention. The series solar system 600 is utilized for providing an output current I_{OUT} and a load voltage V_{L} to an external load LOAD. The series solar system comprises solar modules SLM₁˜SLM_{N}, wherein the structures and operational principles of the solar modules SLM₁˜SLM_{N} are similar to the solar module SLM in FIG. 2. Since in the series solar system 600, the output power generated by each solar module SLM₁˜SLM_{N} can be maximized by means of the methods illustrated in FIG. 3A and FIG. 3B. Thus, the energy conversion efficiency of the series solar system 600 is improved. Besides, in the series solar system 600, the received light intensities of the solar modules SLM₁˜SLM_{N} may be different. For instance, in the series solar system 600, the solar panel SP₁ of the solar module SLM₁ is covered so the received light intensity of the solar panel SP₁ is SUN_{L}, and the received light intensities of the other uncovered solar panels SP₂˜SP_{N} are equal to SUN_{H}. In other words, the photocurrent correspond to the optimum operating point of the solar panel SP₁ of the solar module SLM₁ is different from the photocurrents corresponding to the optimum operating point of the other uncovered solar panel SP₂˜SP_{N}. However, since in the series solar system 600, the magnitudes of the currents passing through the solar panels SP₁˜SP_{N} do not have to be the same by means of each solar panel connected to a DC/DC converter in parallel, each solar panel SP₁˜SP_{N} still can operate at the optimum operating point. That is, the output power of each solar module SP₁˜SP_{N} is maximized by means of the DC/DC converters DCCR₁˜DCCR_{N} of the solar modules SLM₁˜SLM_{N} adjusting their duty cycles according to the illustration in FIG. 4. In addition, the magnitudes of the currents outputted by the solar modules SLM₁˜SLM_{N} are all equal to the output current I_{OUT} provided by the series solar system 600 at the same time.

In addition, in the above-mentioned solar module SLM, the DC/DC converter 210 (or 510) can be a boost converter or a boost-buck converter according to the requirement. For example, when the output current I_{OUT} of the series solar system 600 is mainly determined by the external load LOAD and the magnitude of the output current I_{OUT} determined by the external load LOAD is smaller than the current corresponding to the optimum operating point of the solar panel, each solar panel still can operate at the optimum operating point by means of realizing the DC/DC converter 210 (or 510) with a boost converter (or a boost-buck converter). Since the boost converter and the boost-buck converter are well known to those skilled in the art, the structures and the operational principles of them will not be illustrated for brevity.

In conclusion, the series solar system provided by the present invention has the current-matching function by means of the solar panel connected to the DC/DC converter in parallel. In this way, no matter the solar panel is covered or the magnitude of the current outputted by the solar module determined by the external load is smaller than the photocurrent corresponding to the optimum operating point of the solar panel, the DC/DC converter can adjust its duty cycle for the solar panel operating at the optimum operating point. Consequently, the output power of each solar module is maximized, increasing the energy conversion efficiency of the series solar system.

Those skilled in the art will readily observe that numerous modifications and alterations of the device and method may be made while retaining the teachings of the invention.

What is claimed is:

1. A series solar system with current-matching function, for providing an output current and a load voltage, comprising:
a plurality of solar modules electrically connected to each other in series, each solar module comprising:
a solar panel, for receiving light beams and generating a photocurrent and a photovoltage according to a light intensity;
a DC/DC converter, electrically connected to the solar panel, for converting the photovoltage into an output voltage and converting the photocurrent into the output current according to a power-feedback signal; and
a feedback circuit, electrically connected to the DC/DC converter, for generating the power-feedback signal according to the output voltage and the output current;
wherein a sum of the output voltages generated by the plurality of the solar modules is equal to the load voltage.

2. The series solar system of claim 1, wherein each solar module of the plurality of the solar modules further comprises:
a voltage-stabilizing capacitor, electrically connected to the solar panel in parallel, for stabilizing the photovoltage generated by the solar panel.

3. The series solar system of claim 1, wherein the solar panel comprises:
a plurality of solar cells electrically connected to each other in series.

4. The series solar system of claim 1, wherein the DC/DC converter is a buck converter.

5. The series solar system of claim 1, wherein during a first detecting period, the DC/DC converter operates with a first duty cycle and receives the power-feedback signal corresponding to the first detecting period; during a second detecting period, the DC/DC converter operates with a second duty cycle smaller than the first duty cycle and receives the power-feedback signal corresponding to the second detecting period; when the power-feedback signal corresponding to the second detecting period is larger than the power-feedback signal corresponding to the first detecting period, the DC/DC converter decreases the first duty cycle and the second duty cycle; when the power-feedback signal corresponding to the second detecting period is smaller than the power-feedback signal corresponding to the first detecting period, the DC/DC converter increases the first duty cycle and the second duty cycle.

6. The series solar system of claim 5, wherein the DC/DC converter adjusts the first duty cycle and the second duty cycle so that an output power generated by the solar panel can be maximized in a condition of the light intensity, and currents generated by the plurality of the solar modules are urged to be equal at the same time.

7. The series solar system of claim 1, wherein during a detecting period, the DC/DC converter operates with a first duty cycle and receives the power-feedback signal corresponding to the detecting period; during a prior detecting period adjacent to the detecting period, the DC/DC converter operates with a second duty cycle and receives the power-feedback signal corresponding to the prior detecting period adjacent to the detecting period; the DC/DC converter adjusts the duty cycle of the DC/DC converter according to the power-feedback signal corresponding to the detecting period and the power-feedback signal corresponding to the prior detecting period adjacent to the detecting period.

8. The series solar system of claim 7, wherein when the first duty cycle is larger than the second duty cycle and the power-feedback signal corresponding to the detecting period is larger than the power-feedback signal corresponding to the prior detecting period adjacent to the detecting period, the DC/DC converter increases the duty cycle; when the first duty cycle is smaller than the second duty cycle and the power-feedback signal corresponding to the detecting period is smaller than the power-feedback signal corresponding to the prior detecting period adjacent to the detecting period, the DC/DC converter increases the duty cycle; when the first duty cycle is smaller than the second duty cycle and the power-feedback signal corresponding to the detecting period is larger than the power-feedback signal corresponding to the prior detecting period adjacent to the detecting period, the DC/DC converter decreases the duty cycle; when the first duty cycle is larger than the second duty cycle and the power-feedback signal corresponding to the detecting period is smaller than the power-feedback signal corresponding to the prior detecting period adjacent to the detecting period, the DC/DC converter decreases the duty cycle.

9. The series solar system of claim 7, wherein the DC/DC converter adjusts the duty cycle so that an output power generated by the solar panel can be maximized in a condition of the light intensity, and currents generated by the plurality of the solar modules are urged to be equal at the same time.

10. The series solar system of claim 1, wherein the DC/DC converter comprises:
an output capacitor, for outputting the output voltage;
a diode, having a first end electrically connected to the output capacitor and the solar panel, and a second end;
an inductor, having a first end electrically connected to the second end of the diode, and a second end electrically connected to the output capacitor;
a first power switch, having a first end electrically connected to the first end of the inductor, a second end electrically connected to the solar panel, and a control end; and
a controller, electrically connected to the control end of the first power switch, for controlling a duty cycle of the first power switch according to the power-feedback signal.

11. The series solar system of claim 10, wherein when the first power switch is turned on, the output current passes through the inductor, the first power switch, and the solar panel; when the first power switch is turned off, the output current passes through the inductor and the diode.

12. The series solar system of claim 10, wherein the diode is a Schottky diode, and the first power switch is a Metal Oxide Semiconductor (MOS) transistor.

13. The series solar system of claim 1, wherein the DC/DC converter comprises:
an output capacitor, for outputting the output voltage;
an inductor, having a first end, and a second end electrically connected to the output capacitor;
a first power switch, having a first end electrically connected to the first end of the inductor, a second end electrically connected to the solar panel, and a control end;
a second power switch, having a first end electrically connected to the output capacitor and the solar panel, a second end electrically connected to the first end of the first power switch, and a control end; and
a controller, electrically connected to the control end of the first power switch and the control end of the second power switch, for turning on the first power switch when the second power switch is turned off and turning off the first power switch when the second power switch is turned on, so as to control a duty cycle of the first power switch according to the power-feedback signal.

14. The series solar system of claim 13, wherein when the first power switch is turned on and the second power switch is turned off, the output current passes through the inductor, the first power switch, and the solar panel; when the first power switch is turned off and the second power switch is turned on, the output current passes through the inductor and the second power switch.

15. The series solar system of claim 13, wherein the first power switch and the second power switch are MOS transistors.

16. The series solar system of claim 13, wherein the DC/DC converter further comprises:
a diode, having a first end electrically connected to the output capacitor and the solar panel, and a second end electrically connected to the first end of the inductor.

17. The series solar system of claim 16, wherein the diode is a Schottky diode.

18. The series solar system of claim 1, wherein the DC/DC converter converts the photovoltage into the output voltage according to the power-feedback signal so that an output power generated by the solar panel can be maximized in a condition of the light intensity, and currents generated by the plurality of the solar modules are urged to be equal at the same time.
